(19) United States
(12) Patent Application Publication
(10) Pub. No.: US 2025/0089200 A1
(43) Pub. Date: Mar. 13, 2025

(54) INTEGRATED SERVER CABINET

(71) Applicant: Hebei Qinhuai Data Co., Limited., Zhangjiakou City (CN)

(72) Inventor: Binghua ZHANG, Zhangjiakou City (CN)

(21) Appl. No.: 18/818,562

(22) Filed: Aug. 28, 2024

(30) Foreign Application Priority Data
Sep. 8, 2023 (CN) 202311156401.1

(51) Int. Cl. H05K 7/14; H05K 7/20

(52) U.S. Cl. CPC H05K 7/1489; H05K 7/20736

(57) ABSTRACT

The present disclosure discloses an integrated server cabinet including a cabin body and a cooling fan. The cooling fan is mounted on an inner wall of the cabin body, two cabin doors are hinged to the cabin body, and the two cabin doors are arranged at the cabin body. A heat insulation plate is mounted on the cabin body, and the cabin body is internally provided with a plurality of fixed plates arranged at intervals from top to bottom, where one of the plurality of fixed plates is mounted on a side of the inner wall of the heat insulation plate. A first electric drive pusher and a damping buffer are connected between adjacent two of the plurality of fixed plates, a mounting slot is provided on a side of each of the plurality of fixed plate, and a carrier mesh plate is embedded into the mounting slot.

### CROSS REFERENCE TO RELATED APPLICATION

This application claims priority to Chinese Patent Application No. 202311156401.1, titled “INTEGRATED SERVER CABINET” and filed to the China National Intellectual Property Administration on Sep. 8, 2023, the entire contents of which are incorporated herein by reference.

### TECHNICAL FIELD

The present disclosure relates to the field of photovoltaic cabinet technology, and more particularly, to an integrated server cabinet.

### BACKGROUND

When existing server cabinets are used, their internal pallets are fixed, which leads to a fact that only fixed-size servers can be placed thereon. Once a specification is less than a specified size, this may lead to unstable installation of the servers. However, once the specification is greater than the specified size, this may lead to failed installation of the servers, which reduces flexibility in use of the apparatuses.

### SUMMARY

In existing technologies, internal placement space mostly is fixed, so only servers with fixed sizes can be placed, but it is not convenient for placement of large servers, which leads to a problem of lower flexibility of use of server cabinets. To solve this problem, an objective of the present disclosure is to provide an integrated server cabinet.

To achieve the above objective, the present disclosure adopts following technical solutions. The integrated server cabinet includes a cabin body and a cooling fan. The cooling fan is fixedly mounted on an inner wall at a top of the cabin body, two cabin doors are hinged to a side of the cabin body, and the two cabin doors are openably arranged at an opening of the cabin body. A heat insulation plate is fixedly mounted on the inner wall of the cabin body, and the cabin body is internally provided with a plurality of fixed plates arranged at intervals from top to bottom, where one of the plurality of fixed plates is fixedly mounted on a side of the inner wall of the heat insulation plate. A first electric drive pusher and a damping buffer are connected between adjacent two of the plurality of fixed plates, a mounting slot is provided on a side of each of the plurality of fixed plate, and a carrier mesh plate is embedded into the mounting slot.

Through the above settings, servers with different specifications can be placed, and then the servers are fixed, to prevent the servers from wobbling during use, which can improve the flexibility of the use of the apparatus to a certain extent.

As the preferred technical solutions of the present disclosure, a mobile mechanism is installed in the cabin body, and the mobile mechanism is positioned at a bottom of the cabin body. The mobile mechanism includes a dovetail slot and a groove, both of which are provided at the bottom of the cabin body. Two dovetail slots are symmetrically arranged with the groove as a center, and a dovetail plate is matched and installed in either of the two dovetail slots.

As the preferred technical solutions of the present disclosure, a support plate is fixedly installed on a top of the dovetail plate, a support rack is fixedly installed on a top of the support plate, and a server temperature control apparatus is fixedly installed on a top of the support rack.

As the preferred technical solutions of the present disclosure, a threaded block is slidably installed in the groove, and a threaded rod is screw-mounted in the threaded block, where one end of the threaded rod is fixedly connected to a servo motor, which is fixedly mounted on an inner wall at the bottom of the cabin body. A mounting seat is rotatably mounted at one end of the threaded rod away from the servo motor, and the mounting seat is also fixedly mounted on the inner wall at the bottom of the cabin body.

As the preferred technical solutions of the present disclosure, a fixing sleeve is fixedly mounted at a top of the threaded block, and the fixing sleeve is internally provided with an empty cavity. Four first sliding chutes are circumferentially arranged on an inner wall of the empty cavity, a first slider is slidably mounted in each of the four first sliding chutes, and a circular plate is installed between the four first slides. A spring is fixedly mounted at a bottom of the circular plate, and one end of the spring away from the circular plate is fixedly mounted on the inner wall of the empty cavity.

As the preferred technical solutions of the present disclosure, a sliding sleeve is fixedly mounted at other side of the circular plate, and a circular seat is fixedly connected to one end of the sliding sleeve away from the circular plate. A limit groove is provided at a bottom of the server temperature control apparatus, and a circular groove is provided at an installation site of the circular seat positioned in the limit groove.

Through the above settings, it is convenient to pull the server temperature control apparatus out of the cabin body, to facilitate maintenance of the server temperature control apparatus when it goes wrong, which can improve convenience of maintenance and minimize adverse impacts on the servers caused by failure of the server temperature control apparatus.

As the preferred technical solutions of the present disclosure, a mounting seat is fixedly mounted at the top of the cabin body, a storage battery is installed inside the mounting seat, and a first photovoltaic panel is fixedly mounted at a top of the mounting seat. The first photovoltaic panel is internally provided with an empty cavity, a second photovoltaic panel is slidably installed inside the empty cavity, and an expandable rack is fixedly mounted at one side of the second photovoltaic panel. An L-shaped rack is fixedly connected to a fixed end of the expandable rack, a second electric drive pusher is fixedly mounted at one side of the L-shaped rack, and the second electric drive pusher is fixedly mounted at one side of the mounting seat.

As the preferred technical solutions of the present disclosure, a first connection block is fixedly mounted at one side of the second photovoltaic panel, and a connecting rod is fixedly mounted at one side of the first connection block. A second connection block is fixedly connected to one end of the connecting rod away from the first connection block, and a second slider is fixedly mounted at one side of the second connection block. A second sliding chute is correspondingly provided at an installation site of the second slider at one side of the first photovoltaic panel, a guide rod is fixedly mounted on an inner wall of the second sliding chute, and the second slider is sleeved on an outer wall of the guide rod.

As the preferred technical solutions of the present disclosure, a cross rod is fixedly mounted at one side of the second connection block, and the cross rod is internally provided with an anti-trip slot. An anti-trip plate is slidably mounted on an inner wall of the anti-trip slot, a first cleaning board is fixedly mounted on a bottom of the anti-trip plate, and a bottom of the first cleaning board fits to a top of the first photovoltaic panel. A second cleaning board is fixedly mounted at one side of an opening of the empty cavity at one side of the first photovoltaic panel, and a bottom of the second cleaning board fits to a top of the second photovoltaic panel.

Through the above settings, absorption area of sunlight can be increased, and dust on surfaces of the first photovoltaic panel and the second photovoltaic panel can be wiped, which can avoid adsorption of the dust from adversely affecting efficiency of absorption of the sunlight for the first photovoltaic panel and the second photovoltaic panel.

The present disclosure at least includes following beneficial effects. In the technical solutions adopted by the present disclosure, through cooperation between the fixed plate, the electric drive pusher and the damping buffer, spacing between the carrier mesh plates can be adjusted, and thus placement of servers with different specifications can be implemented, which can improve the flexibility in using the apparatus to a certain extent. In addition, through mutual cooperation between the fixed sleeve, the spring, the sliding sleeve, the dovetail slot and the dovetail plate, it is convenient to pull the server temperature control apparatus out of the cabin body, to facilitate maintenance of the server temperature control apparatus when it goes wrong, which can improve convenience of maintenance and minimize adverse impacts on the servers caused by failure of the server temperature control apparatus.

Meanwhile, under the action of mutual cooperation between the second electric drive pusher, the expandable rack, the first cleaning board and the second cleaning board, extension area of the first photovoltaic panel and of the second photovoltaic panel can be adjusted. Furthermore, dust can be wiped from the surface of the first photovoltaic panel and of the second photovoltaic panel in the process of adjusting the area, which can avoid existence of the dust from adversely affecting absorption of the sunlight.

### BRIEF DESCRIPTION OF THE DRAWINGS

FIG. 1 is a schematic diagram of a three-dimensional structure of an integrated server cabinet proposed in the present disclosure;

FIG. 2 is a schematic diagram of a first local three-dimensional structure of an integrated server cabinet proposed in the present disclosure;

FIG. 3 is a schematic diagram of a local exploded three-dimensional structure of an integrated server cabinet proposed in the present disclosure;

FIG. 4 is a schematic diagram of a second local structure of an integrated server cabinet proposed in the present disclosure;

FIG. 5 is a schematic diagram of a third local structure of an integrated server cabinet proposed in the present disclosure;

FIG. 6 is a schematic diagram of an enlarged structure of A in FIG. 5 of an integrated server cabinet proposed in the present disclosure;

FIG. 7 is a schematic diagram of a local main view cross-section structure of an integrated server cabinet proposed in the present disclosure;

FIG. 8 is a schematic diagram of a fourth local structure of an integrated server cabinet proposed in the present disclosure; and

FIG. 9 is a schematic diagram of an enlarged structure of B in FIG. 8 of an integrated server cabinet proposed in the present disclosure.

Reference numerals in the figures: cabin body 101; cooling fan 102; cabin door 103; heat insulation plate 104; fixed plate 105; first electric drive pusher 106; damping buffer 107; carrier mesh plate 108; mounting seat 109; first photovoltaic panel 110; second photovoltaic panel 111; expandable rack 112; second electric drive pusher 113; connecting rod 114; second slider 115; guide rod 116; cross rod 117; mobile mechanism 200; dovetail plate 201; support plate 202; support rack 203; server temperature control apparatus 204; threaded block 205; threaded rod 206; servo motor 207; mounting seat 208; fixed sleeve 209; first slider 210; circular plate 211; spring 212; sliding sleeve 213; and circular seat 214.

### DETAILED DESCRIPTION

Technical solutions in the embodiments of the present disclosure will be described clearly and completely below in conjunction with the accompanying drawings in the embodiments of the present disclosure. Apparently, the described embodiments are some but not all of the embodiments of the present disclosure. All other embodiments obtained by those of ordinary skills in the art based on the embodiments of the present disclosure without creative efforts shall fall within the protection scope of the present disclosure.

In the description of the present disclosure, it is to be noted that the orientations or positions represented by the terms of “up”, “down”, “inside”, “outside”, “top/bottom” and the like are based on the orientations or positions shown in the accompanying figures, they are merely for ease of a description of the present disclosure and a simplified description instead of being intended to indicate or imply the apparatus or component to have a special orientation or to be configured and operated in a special orientation. Thus, they cannot be understood as limiting of the present disclosure. In addition, terms “first” and “second” are merely for description purposes, and are not construed as indicating or implying relative importance.

In the description of the present disclosure, it is to be noted that unless specified or limited otherwise, terms such as “mounted”, “provided with”, “sleeved with/to” and “connection” should be understood in a broad sense. For example, the “connection” may be a fixed connection, a detachable connection or integrated connection, a mechanical connection or an electrical connection, a direct connection or indirect connection by means of an intermediary, or an internal communication between two components. For those of ordinary skills in the art, the specific meanings of the above terms in the present disclosure may be understood according to specific conditions.

When existing server cabinets are used, their internal pallets are fixed, which leads to a fact that only fixed-size servers can be placed thereon. Once a specification is less than a specified size, this may lead to unstable installation of the servers. However, once the specification is greater than the specified size, this may lead to failed installation of the servers, which reduces flexibility in use of the apparatuses.

In addition, to cool the servers, cooling apparatuses may be fixedly mounted inside the apparatuses, but it is not convenient to repair the cooling apparatuses once they go wrong.

Therefore, how to improve the existing server cabinets to adapt to different sizes of servers has become an issue that needs to be urgently settled for those skilled in the art.

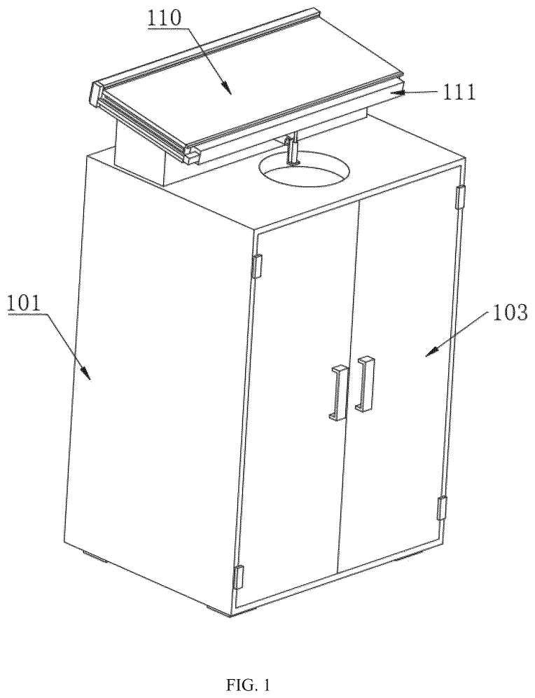

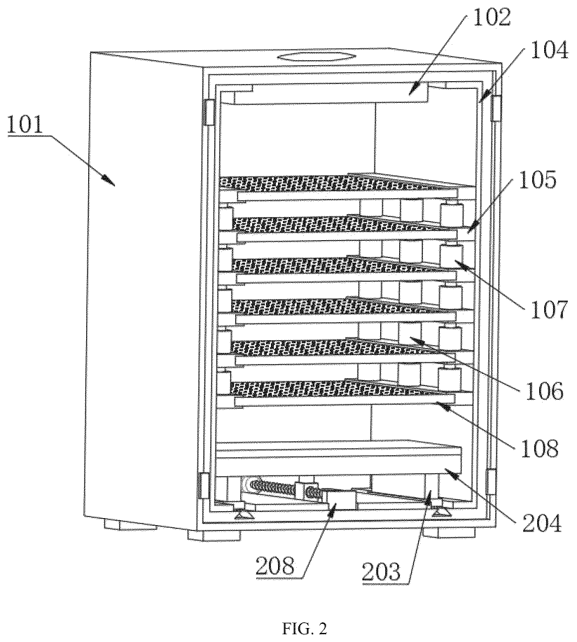

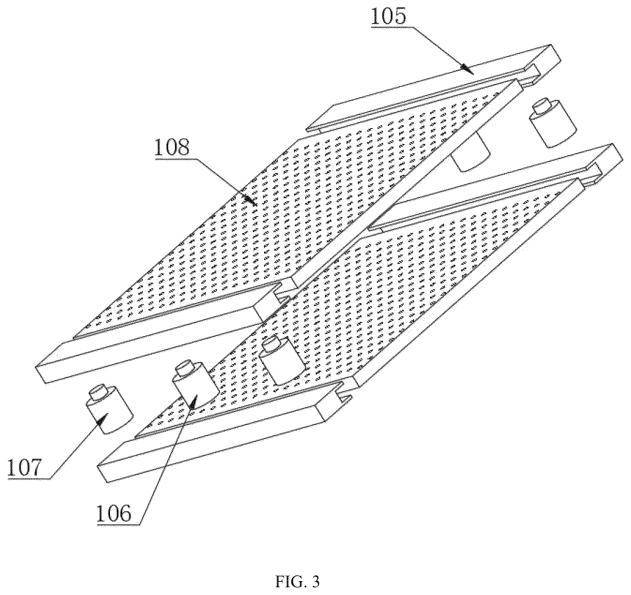

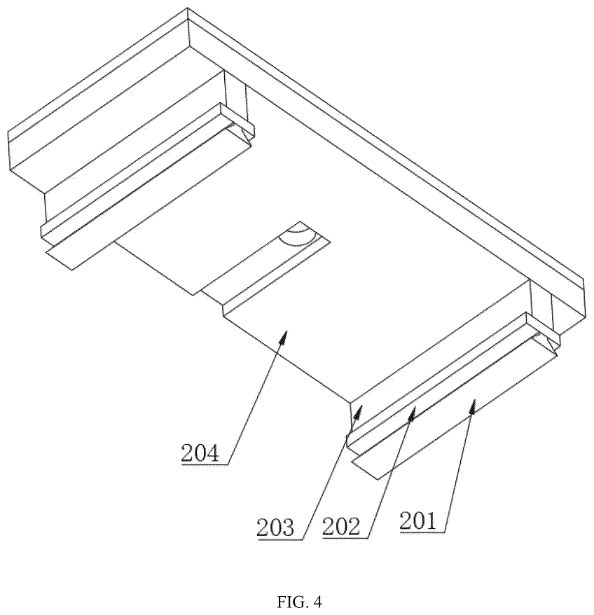

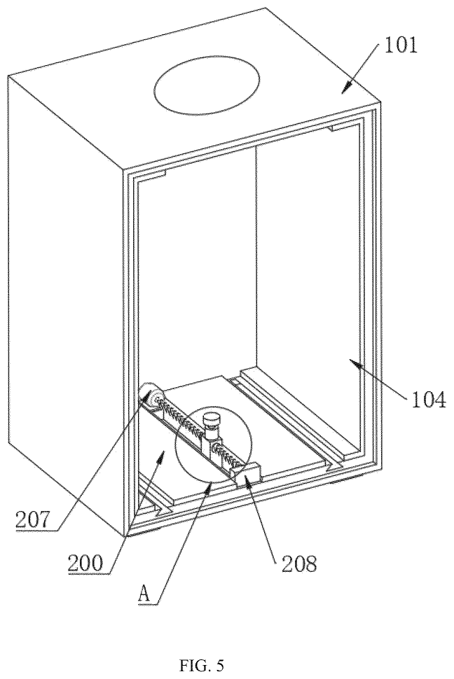

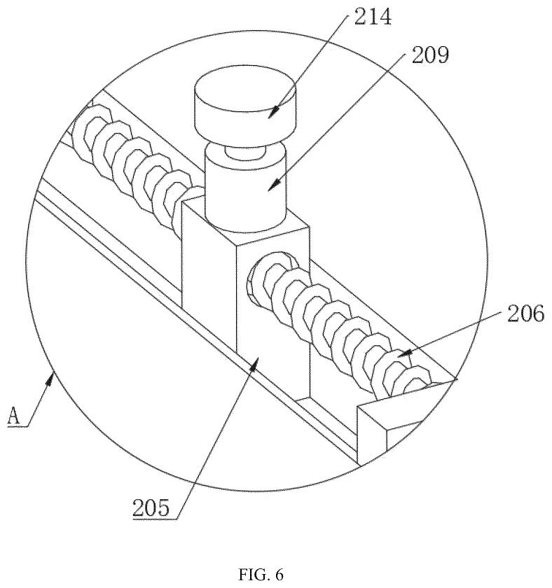

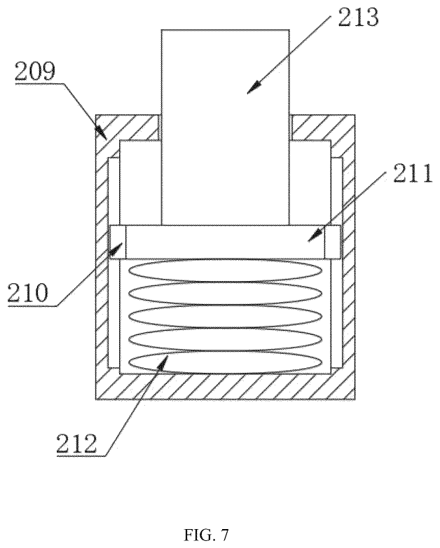

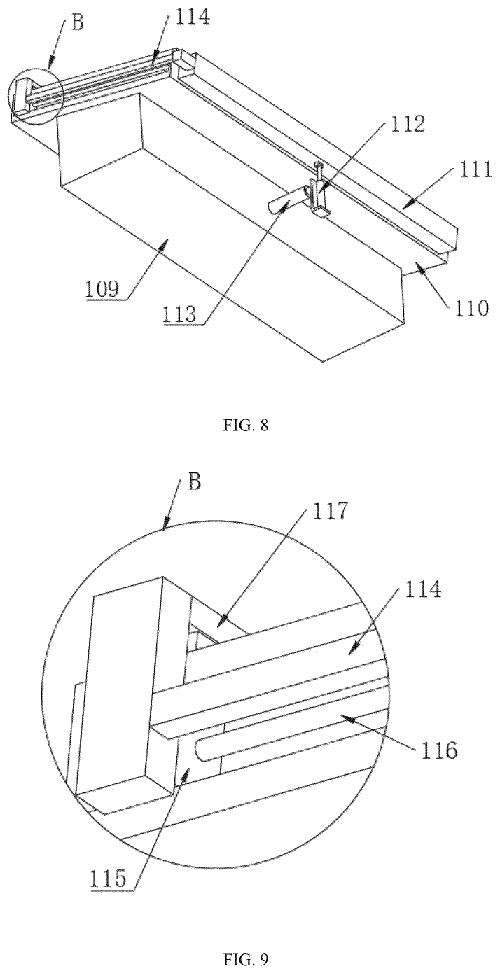

In an implementable embodiment, referring to FIGS. 1 to 9, an integrated server cabinet includes a cabin body 101 and a cooling fan 102. Cooling of internal servers can be realized by use of the cooling fan 102. The cooling fan 102 is fixedly mounted on an inner wall at a top of the cabin body 101, and a circular groove is provided at an installation site of the cooling fan 102 at the top of the cabin body 101. A dustproof mesh is mounted on an inner wall of the circular groove. Two cabin doors 103 are hinged to a side of the cabin body 101. Tightness of the apparatus can be improved by use of the cabin doors 103. The two cabin doors 103 are openably arranged at an opening of the cabin body 101. Specifically, one side of either of the two cabin doors 103 is hinged to a side of the opening of the cabin body 101. A heat insulation plate 104 is fixedly mounted on the inner wall of the cabin body 101. External heat can be insulated by means of the heat insulation plate 104, which can reduce temperature inside the cabin body 101 to a certain extent.

The cabin body 101 is internally provided with a plurality of fixed plates 105 arranged at intervals from top to bottom, where one of the plurality of fixed plates 105 is fixedly mounted on a side of the inner wall of the heat insulation plate 104. A first electric drive pusher 106 and a damping buffer 107 are connected between adjacent two of the plurality of fixed plates 105. That is, the first electric drive pusher 106 and the damping buffer 107 are fixedly mounted on the top of each fixed plate 105, and one fixed plate 105 is respectively mounted at a piston rod end of each first electric drive pusher 106 and at a piston rod end of each damping buffer 107. A mounting slot is provided on a side of each fixed plate 105, and a carrier mesh plate 108 is embedded into the mounting slot. The fixed plate 105 can be pushed by the first electric drive pusher 106, and the fixed plate 105 can be cushioned during its movement by means of the damping buffer 107.

In practical applications, two columns of fixed plate components may be arranged in the cabin body 101, and the two columns of fixed plate components are arranged on two internal sides of the cabin body 101 and are arranged with respect to each other. Each column of fixed plate components is provided with the plurality of fixed plates 105, such that left and right ends of each carrier mesh plate 108 are supported by the fixed plate 105 (as shown in the figures). In this way, support of the carrier mesh plate 108 is improved.

In practical applications, because server rooms are classified into Class A, Class B and Class C, temperature and humidity requirements for the three types of server rooms are different, and standards thereof are successively lowered. The Class A and Class B server rooms have the same requirements, temperature being 23±1° C., and humidity being 40% to 55%. The class C server room has a temperature of 18° C. to 28° C. and humidity of 35% to 75%. To meet needs of the servers to work at the optimum temperature, it is required to cool down interior of the cabin body 101, which needs to use the server temperature control apparatus 204 inside the cabin body 101. The server temperature control apparatus is used to refrigerate the cabin body 101, such that the cabin body 101 can be cooled down when its internal temperature is higher. In this way, it can be ensured that the servers can work in environment having stable temperature.

To facilitate maintenance and operation of the server temperature control apparatus 204, in an implementable embodiment, a mobile mechanism 200 is installed on the inner wall at the bottom of the cabin body 101, and the mobile mechanism 200 is positioned at the bottom of the cabin body 101. The mobile mechanism 200 is used to move the server temperature control apparatus 204 inside and outside the cabin body 101 to facilitate users' maintenance and operation of the server temperature control apparatus 204.

Specifically, the mobile mechanism 200 includes a dovetail slot and a groove, where both the dovetail slot and the groove are provided at the bottom of the cabin body 101. Two dovetail slots are symmetrically arranged with the groove as a center, and a dovetail plate 201 is matched and installed in either of the two dovetail slots. Movement of the server temperature control apparatus 204 can be guided and limited by means of mutual cooperation between the dovetail slot and the dovetail plate 201. A support plate 202 is fixedly installed on a top of the dovetail plate 201, a support rack 203 is fixedly installed on a top of the support plate 202, and the server temperature control apparatus 204 is fixedly installed on a top of the support rack 203. The server temperature control apparatus 204 can be supported by means of mutual cooperation between the support plate 202 and the support rack 203. A threaded block 205 is slidably installed in the groove, and a threaded rod 206 is screw-mounted in the threaded block 205. One end of the threaded rod 206 is fixedly connected to a servo motor 207, and the servo motor 207 is fixedly mounted on an inner wall at the bottom of the cabin body 101. The threaded rod 206 can be driven to rotate through the servo motor 207. By means of rotation of the threaded rod 206, the threaded block 205 can be driven to move. By means of movement of the threaded block 205, the server temperature control apparatus 204 can be driven to move, such that the server temperature control apparatus 204 can be easily pulled out of the cabin body 101, making it convenient to repair the server temperature control apparatus 204 when it goes wrong. The mounting seat 208 is also fixedly mounted on the inner wall at the bottom of the cabin body 101.

A fixing sleeve 209 is fixedly mounted at a top of the threaded block 205, and the fixing sleeve 209 is internally provided with an empty cavity. Four first sliding chutes are circumferentially arranged on an inner wall of the empty cavity, a first slider 210 is slidably mounted in each of the four first sliding chutes, and a circular plate 211 is installed between the four first slides 210. Through mutual cooperation between the first sliding chute and the first slider 210, lifting of the circular plate 211 can be guided and limited. A spring 212 is fixedly mounted at a bottom of the circular plate 211. The lifting of the circular plate 211 can be cushioned by means of the spring 212. One end of the spring 212 away from the circular plate 211 is fixedly mounted on the inner wall of the empty cavity. A sliding sleeve 213 is fixedly mounted at other side of the circular plate 211. A circular seat 214 is fixedly connected to one end of the sliding sleeve 213 away from the circular plate 211. A limit groove is provided at a bottom of the server temperature control apparatus 204, and a circular groove is provided at an installation site of the circular seat 214 positioned in the limit groove. By means of mutual cooperation between the circular seat 214 and the circular groove, fixation of the server temperature control apparatus 204 can be achieved. Thus, when the threaded block 205 moves, the server temperature control apparatus 204 can be driven to move.

A mounting seat 109 is fixedly mounted at the top of the cabin body 101, a storage battery is installed inside the mounting seat 109, and a first photovoltaic panel 110 is fixedly mounted at a top of the mounting seat 109. The first photovoltaic panel 110 is internally provided with an empty cavity, a second photovoltaic panel 111 is slidably installed inside the empty cavity, and an expandable rack 112 is fixedly mounted at one side of the second photovoltaic panel 111. An L-shaped rack is fixedly connected to a fixed end of the expandable rack 112, a second electric drive pusher 113 is fixedly mounted at one side of the L-shaped rack, and the second electric drive pusher 113 is fixedly mounted at one side of the mounting seat 109. The first photovoltaic panel 110 and the second photovoltaic panel 111 absorb sunlight, and then convert it into electric energy, and then store the electric energy through the storage battery. The storage battery can provide energy to the cooling fan 102, the first electric drive pusher 106, the second electric drive pusher 113, the server temperature control apparatus 204, and the servo motor 207, such that the second electric drive pusher 113 can be started to drive. The second electric drive pusher 113 can pull or push the L-shaped rack. Thus, the second photovoltaic panel 111 can be driven to slide inside the empty cavity to adjust the area of the first photovoltaic panel 110 and of the second photovoltaic panel 111.

A first connection block is fixedly mounted at one side of the second photovoltaic panel 111, and a connecting rod 114 is fixedly mounted at one side of the first connection block. A second connection block is fixedly connected to one end of the connecting rod 114 away from the first connection block, and a second slider 115 is fixedly mounted at one side of the second connection block. A second sliding chute is correspondingly provided at an installation site of the second slider 115 at one side of the first photovoltaic panel 110, and a guide rod 116 is fixedly mounted on an inner wall of the second sliding chute, and the second slider 115 is sleeved on an outer wall of the guide rod 116. During the sliding process of the second photovoltaic panel 111, the connecting rod 114 can be controlled to drive the second slider 115 to slide on the guide rod 116.

A cross rod 117 is fixedly mounted at one side of the second connection block, the cross rod 117 is internally provided with an anti-trip slot, and an anti-trip plate is slidably mounted on an inner wall of the anti-trip slot. A first cleaning board is fixedly mounted on a bottom of the anti-trip plate, and a bottom of the first cleaning board fits to a top of the first photovoltaic panel 110. A second cleaning board is fixedly mounted at one side of an opening of the empty cavity at one side of the first photovoltaic panel 110, and a bottom of the second cleaning board fits to a top of the second photovoltaic panel 111. During its sliding process, the second slider 115 can drive the cross rod 117 to slide, such that dust on the surface of the first photovoltaic panel 110 can be wiped, and the second cleaning board can be controlled to wipe the dust on the surface of the second photovoltaic panel 111.

Specifically, when in use, a user may insert the dovetail plate 201 into the dovetail slot, then place the circular seat 214 into the limit groove, and then push the server temperature control apparatus 204. In its process of movement, the server temperature control apparatus 204 can drive the circular seat 214 to move within the limit groove. When the circular seat 214 moves to the circular groove, the circular seat 214 may enter the circular groove, thereby achieving fixation of the server temperature control apparatus 204. Next, the servo motor 207 may be started, such that the servo motor 207 can drive the threaded rod 206 to rotate, and the threaded rod 206 can drive the threaded block 205 to move during rotation. Through the movement of the threaded block 205, the server temperature control apparatus 204 can be driven to move, thus the server temperature control apparatus 204 can be driven to move. In this way, it is convenient to pull the server temperature control apparatus 204 out of the cabin body, to facilitate maintenance of the server temperature control apparatus 204 when it goes wrong, which can improve convenience of maintenance and minimize adverse impacts on the servers caused by failure of the server temperature control apparatus 204. Next, the first electric drive pusher 106 may also be started, such that the first electric drive pusher 106 can push the fixed plate 105, to adjust height of the carrier mesh plate 108. The use of a plurality of first electric drive pushers 106 can adjust spacing between the carrier mesh plates 108, and thus placement of servers with different specifications can be implemented, which can improve the flexibility in using the apparatus. Next, the cooling fan 102 can be started, and the cooling fan 102 may pump outside air into the cabin body 101. When the air passes through the dustproof mesh, the dustproof mesh can filter the dust. Next, the filtered air is blown to the servers inside the cabin body 101 to cool down the server.

Next, the second electric drive pusher 113 is started, and the second electric drive pusher 113 can pull or push the L-shaped rack, to drive the second photovoltaic panel 111 to slide in the empty cavity, thereby achieving adjustment of the area of the first photovoltaic panel 110 and of the second photovoltaic panel 111. In the process of sliding, the second photovoltaic panel 111 can control the connecting rod 114 to drive the second slider 115 to slide on the guide rod 116. In the process of sliding, the second slider 115 can drive the cross rod 117 to slide, to wipe the dust on the surface of the first photovoltaic panel 110. Furthermore, the second cleaning board can be controlled to wipe the dust on the surface of the second photovoltaic panel 111.

It should be noted that the cooling fan 102, the first electric drive pusher 106, the second electric drive pusher 113, the damping buffer 107, the server temperature control apparatus 204 and the servo motor 207 are apparatuses or devices in the prior art, or apparatuses or devices that can be realized in the prior art. Power supply, specific compositions and principles thereof are clear to those skilled in the art, and thus details thereof are omitted here.

The above embodiments are merely preferred embodiments of the present disclosure, but the protection scope of the present disclosure is not limited thereto. Any equivalent substitutions or modifications made by a person of skilled in the art according to the technical solutions of the present disclosure and conceptions thereof within the technical scope disclosed in the present disclosure shall fall within the protection scope of the present disclosure.

What is claimed is:

1. An integrated server cabinet comprising a cabin body (101) and a cooling fan (102), wherein the cooling fan (102) is fixedly mounted on an inner wall at a top of the cabin body (101), two cabin doors (103) are hinged to a side of the cabin body (101), and the two cabin doors (103) are openably arranged at an opening of the cabin body (101); and
a heat insulation plate (104) is fixedly mounted on the inner wall of the cabin body (101), the cabin body (101) is internally provided with a plurality of fixed plates (105) arranged at intervals from top to bottom, one of the plurality of fixed plates (105) is fixedly mounted on a side of the inner wall of the heat insulation plate (104), a first electric drive pusher (106) and a damping buffer (107) are connected between adjacent two of the plurality of fixed plates (105), a mounting slot is provided on a side of each of the plurality of fixed plate (105), and a carrier mesh plate (108) is embedded into the mounting slot.

2. The integrated server cabinet according to claim 1, wherein a mobile mechanism (200) is installed in the cabin body (101), and the mobile mechanism (200) is positioned at a bottom of the cabin body (101); and
the mobile mechanism (200) comprises a dovetail slot and a groove, both the dovetail slot and the groove are provided at the bottom of the cabin body (101), two dovetail slots are symmetrically arranged with the groove as a center, and a dovetail plate (201) is matched and installed in either of the two dovetail slots.

3. The integrated server cabinet according to claim 2, wherein a support plate (202) is fixedly installed on a top of the dovetail plate (201), a support rack (203) is fixedly installed on a top of the support plate (202), and a server temperature control apparatus (204) is fixedly installed on a top of the support rack (203).

4. The integrated server cabinet according to claim 3, wherein a threaded block (205) is slidably installed in the groove, a threaded rod (206) is screw-mounted in the threaded block (205), one end of the threaded rod (206) is fixedly connected to a servo motor (207), and the servo motor (207) is fixedly mounted on an inner wall at the bottom of the cabin body (101).

5. The integrated server cabinet according to claim 4, wherein a mounting seat (109208) is rotatably mounted at one end of the threaded rod (206) away from the servo motor (207), and the mounting seat (109208) is further fixedly mounted on the inner wall at the bottom of the cabin body (101).

6. The integrated server cabinet according to claim 5, wherein a fixing sleeve (209) is fixedly mounted at a top of the threaded block (205); and
the fixing sleeve (209) is internally provided with an empty cavity, four first sliding chutes are circumferentially arranged on an inner wall of the empty cavity, a first slider (210) is slidably mounted in each of the four first sliding chutes, a circular plate (211) is installed between the four first slides (210), a spring (212) is fixedly mounted at a bottom of the circular plate (211), and one end of the spring (212) away from the circular plate (211) is fixedly mounted on the inner wall of the empty cavity.

7. The integrated server cabinet according to claim 6, wherein a sliding sleeve (213) is fixedly mounted at other side of the circular plate (211); and
a circular seat (214) is fixedly connected to one end of the sliding sleeve (213) away from the circular plate (211), a limit groove is provided at a bottom of the server temperature control apparatus (204), and a circular groove is provided at an installation site of the circular seat (214) positioned in the limit groove.

8. The integrated server cabinet according to claim 7, wherein a mounting seat (109) is fixedly mounted at the top of the cabin body (101), a storage battery is installed inside the mounting seat (109), and a first photovoltaic panel (110) is fixedly mounted at a top of the mounting seat (109); and
the first photovoltaic panel (110) is internally provided with an empty cavity, a second photovoltaic panel (111) is slidably installed inside the empty cavity, an expandable rack (112) is fixedly mounted at one side of the second photovoltaic panel (111), an L-shaped rack is fixedly connected to a fixed end of the expandable rack (112), a second electric drive pusher (113) is fixedly mounted at one side of the L-shaped rack, and the second electric drive pusher (113) is fixedly mounted at one side of the mounting seat (109).

9. The integrated server cabinet according to claim 8, wherein a first connection block is fixedly mounted at one side of the second photovoltaic panel (111), a connecting rod (114) is fixedly mounted at one side of the first connection block, a second connection block is fixedly connected to one end of the connecting rod (114) away from the first connection block, a second slider (115) is fixedly mounted at one side of the second connection block, a second sliding chute is correspondingly provided at an installation site of the second slider (115) at one side of the first photovoltaic panel (110), a guide rod (116) is fixedly mounted on an inner wall of the second sliding chute, and the second slider (115) is sleeved on an outer wall of the guide rod (116).

10. The integrated server cabinet according to claim 9, wherein a cross rod (117) is fixedly mounted at one side of the second connection block, the cross rod (117) is internally provided with an anti-trip slot, an anti-trip plate is slidably mounted on an inner wall of the anti-trip slot, a first cleaning board is fixedly mounted on a bottom of the anti-trip plate, a bottom of the first cleaning board fits to a top of the first photovoltaic panel (110), a second cleaning board is fixedly mounted at one side of an opening of the empty cavity at one side of the first photovoltaic panel (110), and a bottom of the second cleaning board fits to a top of the second photovoltaic panel (111).
